(19) United States
(12) Patent Application Publication
(10) Pub. No.: US 2018/0119282 A1
(43) Pub. Date: May 3, 2018

(54) High Hardness Soft Film Structure

(71) Applicant: G2F Tech Co., Ltd., Taipei City (TW)

(72) Inventor: Cheng-Chi Lu, Taipei City (TW)

(21) Appl. No.: 15/708,064

(22) Filed: Sep. 18, 2017

(30) Foreign Application Priority Data
Nov. 3, 2016 (TW) 105216744

(51) Int. Cl. C23C 16/50; C23C 14/24; C23C 14/34

(52) U.S. Cl. CPC C23C 16/50; C23C 14/34; C23C 14/24

(57) ABSTRACT

A high hardness soft film structure, consisting a middle substrate layer, an upper top coating, upper hard coatings or upper anti-pollution layers, a first lower top coating, and lower hard coatings or second lower top coatings and conductive metal mesh layers, the top coatings and a plurality of hard coatings of high hardness material are coated on the upper and lower side surfaces of the middle substrate layer with high light transmittance to increase scratch and wear resistivity of the entire structure from external forces, or the low surface energy, upper anti-pollution layer is applied to cover one side of the outermost upper hard coating, as well as applying coatings of the second lower top coating, and the conductive metal mesh layer conductive material, in achieving the high hardness, anti-pollution, and conductive soft film structure for optical use.

### FIELD OF THE INVENTION

The present disclosure relates to a high hardness soft film structure for use in packaging for food products and medicine products.

### BACKGROUND

Soft films (plastic substrates) are replacing glass substrates and becoming the future trend of next generation display materials. Because soft films possess advantages including being light, thin, impact endurance, and foldable compared to glass substrates, they have applications in many portable and wearable display devices, which increases serviceable life as well as adding to its use range. However, the hardness of soft films is inferior to glass substrates, thus hard coating is usually carried out on the surface of the soft film. Currently soft films have the following applications in the optoelectronics industry: (1) Transparent conductive film, wherein the characteristics of the soft film is used to coat the transparent conductive film to serve as an electrode, with applications in touch panel screens, liquid crystal display panels, (LCD panels), organic light emitting diodes (OLED), electronic books, (e-books), and the like, which enables increasing the competitiveness of products. Apart from being lighter and thinner, the advantages of foldable substrates are more importantly attracting future applications in the optoelectronics industry, and is the primary reason why they are replacing glass substrates. (2) Anti-reflection/Anti-static film, wherein the anti-reflection film is able to increase contrast, reduce reflection, and increase penetration rate. Furthermore, the design of the film layer still enables anti-static, durability against pollution, and anti-ultraviolet irradiation destructive functions. The past requirement to overlay glass with an anti-reflection film has clearly reduced, and has been replaced by overlaying an optical film, such as a polarizer, a brightener film, and the like, in order to increase the functionality of products. (3) Hard Coating, wherein a soft film with insufficient surface hardness is overlaid with an upper hard coating, such as polymethyl methacrylate (PMMA), which is able to substantially increase the surface hardness of soft films, thereby increasing the serviceable life of products. Product applications include: touch panels, polarizers, and all types of plastic molded displays. (4) Light Storage, such as CD-R (Compact Disc-Recordable), DVD-R (Digital Video Disc-Recordable), etc., wherein a polycarbonate (PC) substrate is overlaid with a reflecting layer. (5) Other applications: product applications requiring other surface treatment of soft films still exist, including plating a PI (Polyamide) film with Cu (copper) film, to serve as a plated copper foil conductive electrode, which is a FPC (Flexible Print Circuit) manufactured substrate material. In addition, other surface treatment methods of soft films have been developed for the purpose to increase the functionality of products, including smart windows, sheathing paper, and blocking layers overlaid to reduce water and oxygen permeation.

Surface treatment methods can be divided into a dry-type manufacturing process and a wet-type manufacturing process, wherein a dry-type manufacturing process may use inorganic compounds or inorganic oxides including aluminum oxide, silicon oxide, magnesium oxide, and adopts a physical vapor deposition (PVD) method, including a vacuum evaporation method, sputter coating method, and an ion plating method, or a chemical vapor deposition (CVD) method, including a plasma chemical vapor deposition method, thermal chemical vapor deposition method, and an optical chemical vapor deposition method, to form a surface treated film with an inorganic compound vapor coating. In the surface treatment method using a plasma CVD method to form a surface treated film using silicon oxide as the principal constituent, because the substrate surface is subjected to plasma heating or ionic, free radical impinging affects, during the covering stage, the dry-type manufacturing process still results in problems of unstable physical properties due to the relatively high temperature that easily affects the quality of the plastic substrate, and the finish products easily bend and crack. In addition, the wet-type manufacturing process, may use photo-hardened or thermal-hardened resin coating method, wherein an organic-inorganic mixed material is coated on a substrate. Regarding prior art research on wet-type surface hardened film processing methods, Taiwan Patent No. 420636 discloses a flexible plastic substrate with low reflecting color anti-reflective coating layer, comprising a flexible plastic substrate with a refractive index range from 1.55 to 1.71. The flexible plastic substrate is provided with a first surface and a second surface, wherein an organic hard film is deposited on the first surface of the substrate; moreover, the first surface carries an optical article with anti-reflective coating layer that is laminated on the organic hard film. The anti-reflective coating layer is composed from a high refractive index material and a low refractive index material, and the anti-reflective coating layer provides a reflectance below 1%. Furthermore, regarding the prior art on surface hard coatings, Taiwan Patent No. 201606591 discloses a laminated thin film for touch control panel and use thereof, wherein the laminated thin film is a resin layer with a pencil hardness greater than H. The particles are selected from at least one type from among the group comprising silicon oxide particles, barium sulfate particles, aluminum oxide particles, and calcium carbonate particles. And Taiwan Patent No. 1546198 discloses a gas barrier film with high gas barrier property that is exceptionally reproducible, wherein the gas barrier film is composed of layers of a [A] layer and a [B] layer successively accumulated on at least one surface of a high polymer substrate, wherein the [A] layer is a crosslinking resin layer with a pencil hardness of H˜3H and a surface free energy less than 45 mN/m; the [B] layer is a silicon containing inorganic layer with a thickness of 10˜1000 nm. Any one of the [B1] layers comprises layers of coexisting phases of zinc oxide, silicon dioxide, and aluminum oxide; and any one of [B2] layers comprises layers of coexisting phases of zinc sulfate and silicon dioxide.

In addition, regarding a transparent conductive film that has undergone the wet-type surface hardened film process of prior art, Taiwan Patent No. 1480164 discloses a thin film layer structured from silicon oxide among the two laminated transparent conductive films is formed using chemical vapor deposition (CVD). Moreover, a transparent hard coating made up of resin is formed on a single surface or on both surfaces of a transparent plastic film, and the hard coating formed on the surfaces of the transparent plastic film is used to conceal scratches originally present on the transparent plastic film, which further forms surface slidability or surface strength improvement of the transparent film substrate with hard coating. Hence, scratches on the transparent film substrate are prevented from occurring when carrying out post processing. In particular, when forming the hard coating on the transparent plastic film surfaces on the sides of a transparent conductive layer, apart from the aforementioned aspects, the invention is also able to stabilize conductivity of the transparent conductive film. The resin used for the hard coating is preferably able to cause the hard coating to have a pencil hardness greater than 2H, and can be a transparent resin, such as melamine resin, ultraviolet-hardened acrylic resin, or a resin ester, with a preferable thickness of 1˜7 μm. Furthermore, a pattern of interference fringes is produced when forming the hard coating. However, when forming the pattern of interference fringes, an interference prevention layer (thickness is approximately 10˜50 nm, with a preferable thickness of approximately 20˜30 nm) made up from resin and particulates of high refractive index is preferably disposed between the aforementioned transparent plastic film and the hard coating. Acrylic resin, polyester resin, and the like, may serve as the aforementioned resin, and particulates made from titanium oxide, zirconium oxide, and the like, may be used for the aforementioned particulates of high refractive index. The aforementioned transparent conducting layer is preferably a thin film layer made from ITO (Indium Tin Oxide).

Regarding multilayer stacked structure films of the prior art, Taiwan Patent No. 1510365 discloses a multi-layered plastic substrate, wherein a first organic or organic-inorganic mixed layer, a gas blocking layer, and a second organic or organic-inorganic mixed layer are laminated on two surfaces of two connected plastic film layers. At least one of the first or second organic or organic-inorganic mixed layers is formed as a composition. In addition, Taiwan Patent No. I477637 discloses a coated article with hard coating, comprising a hard base, a joining layer formed on the base, and a nano hard coating formed on the joining layer. The nano hard coating comprises a multiple layers of the TiAlN (Titanium Aluminum Nitride) layer and multiple layers of the SiN (Silicon Nitride) layer. The aforementioned TiAlN layers and the SiN layers are alternately stacked, and after alternating deposition of the aforementioned TiAlN layers and the SiN layers, a nitriding heat treatment is carried out to produce the nano hard coating. A magnetron sputtering equipment preparation method is used in the preparation of the coated article provided with a relatively high hardness, wear resistance, and good high temperature antioxidant properties. However, none of the above-mentioned prior art inventions of structures with high flexibility and thinness are provided with high hardness, anti-pollution, and conductive soft film integration. If such an integration is implemented, then it would certainly stimulate a major development for industries such as packaging for food products and medicine products, and has flexible thin film applications for electronic component use in solar cells, electronic paper, organic electroluminescent (EL) displays, and the like, and serve as an important cornerstone for these industries to facilitate entry into the next generation of product development.

Referring first to FIG. 1, which shows a cross sectional view of a high hardness soft film structure of the prior art, wherein two side surfaces of a middle substrate layer 101 of a high hardness soft film structure 1 are covered with an upper top coating 102 and a lower upper top coating 103, respectively. The function of the top coatings lies in providing the interface between the middle substrate layer 101 and hard coatings with functional group affinity, to achieve a heterogeneous interfaces coupling effect, the thickness of which is greater than 10 μm, and generally lies between 10˜20 μm. An upper hard coating 104 covers the upper top coating 102 adjoining one side surface of the middle substrate layer 101, and a lower hard coating 105 covers the lower upper top coating 103 adjoining the other side surface of the middle substrate layer 101. In order for the hard coatings to achieve a surface pencil hardness greater than H, the manufacturing process generally uses an acrylic material coating with a thickness greater than 30 μm, which generally lies between 30˜40 μm, and a thickness of 100˜188 μm is generally selected for the middle substrate layer 101. Usually, a total thickness greater than 200 μm is achieved after the hard film treatment; moreover, taking into consideration the requirements for surface hardness and adhesive force, the total thicknesses of the hard coatings and the top coatings cannot be correspondingly effectively reduced. Even if a total thickness of 135 μm is achieved, the optical transmittance, adhesive force, and rollability effects are still less than perfect. Using a touch control panel as an example application area, as depicted in FIG. 5, which shows a cross sectional view of a conductive glass substrate structure 5 of the prior art, wherein, under normal conditions, the glass substrate is provided with a touch control function, and needs a conductive film to be disposed on a lower portion of one side of a glass layer 501. The conductive film supports the weight of a conductive metal mesh layer 503 on one side of a plastic substrate layer 502. The so-called metal mesh can be provided with a pattern structured directional conduction function.

### SUMMARY

The present disclosure is a high hardness soft film structure, comprising a middle substrate layer, an upper top coating, at least one upper hard coating or at least one anti-pollution layer, a first lower top coating, and at least one lower hard coating or a second lower top coating, and at least one conductive metal mesh layer, whereby the structure is correspondingly constructed and has characteristics including: top coatings and a plurality of hard coatings of high hardness material are successively applied to the upper and lower sides of the middle substrate layer with high light transmittance to increase scratch and wear resistivity of the entire structure from external forces, or one side of the outermost upper hard coating is covered with the low surface energy, anti-pollution layer; and the second lower top coating and the conductive metal mesh layer material are successively applied to the first lower hard coating. Accordingly, embodiments of the present invention achieve high hardness, anti-pollution, and conductive soft film structure for optical use. The present utility model is a multilayer hardened layered structure that is distinct and differentiable from prior art, and is indeed provided with originality, advancement, and practical effectiveness.

To enable a further understanding of said objectives and the technological methods of the invention herein, a brief description of the drawings is provided below followed by a detailed description of the preferred embodiments.

### BRIEF DESCRIPTION OF THE DRAWINGS

FIG. 1 is a cross sectional view of a high hardness soft film structure of the prior art.

FIG. 2 is a cross sectional view of a high hardness soft film structure of embodiments of the present invention.

FIG. 3 is a cross sectional view of the high hardness soft film structure with an anti-pollution layer according to embodiments of the present invention.

FIG. 4-1 is a structural view of a single hard coating according to embodiments of the present invention.

FIG. 4-2 is a structural view of a two-layer hard coating according to embodiments of the present invention.

FIG. 4-3 is a structural view of a tri-layer hard coating according to embodiments of the present invention.

FIG. 4-4 is a drawing of the single anti-pollution layer according to embodiments of the present invention.

FIG. 4-5 is a structural view of the single hard coating and the single anti-pollution layer according to embodiments of the present invention.

FIG. 4-6 is a structural view of the two-layer hard coating and the single anti-pollution layer according to embodiments of the present invention.

FIG. 5 is a cross sectional view of a conductive glass substrate structure of the prior art.

FIG. 6 is a cross sectional view of the high hardness soft film structure with a conductive layer according to embodiments of the present invention.

FIG. 7 is a cross sectional view of the high hardness soft film structure with the anti-pollution layer and the conductive layer according to embodiments of the present invention.

### DETAILED DESCRIPTION OF THE PREFERRED EMBODIMENTS

The following description uses specific concrete examples to describe the embodiment modes of embodiments of the present invention. Persons skilled in the related art can easily deduce other advantages and effects of embodiments of the present invention from the content disclosed in the specification. Embodiments of the present invention can also use other different concrete embodiments to clarify its performance and applications. Each detail described in the specification can also be based on a different perspective and application, enabling various types of modifications and alterations to be carried out without deviating from the spirit of embodiments of the present invention.

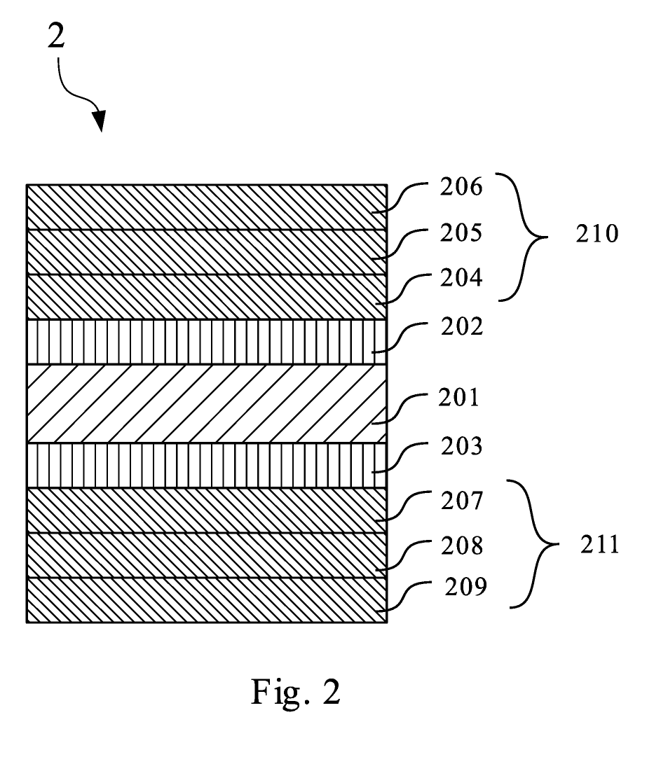

Referring to FIG. 2, which shows a cross sectional view of a high hardness soft film structure of embodiments of the present invention, wherein a high hardness soft film structure 2 comprises a middle substrate layer 201 disposed between an upper top coating 202 and a first lower top coating 203, that is, the two side surfaces of the middle substrate layer 201 are respectively covered with the upper top coating 202 and the first lower top coating 203. The upper top coating 202 is disposed between the middle substrate layer 201 and a first upper hard coating 204, while the first lower top coating 203 is disposed between the middle substrate layer 201 and a lower hard coating 211. The function of the top coatings lies in providing the interface between the middle substrate layer and the hard coatings with functional group affinity, to achieve a heterogeneous interfaces coupling effect, the thickness of which is ≤10 μm, and lies between 50 nm˜10 μm. An upper hard coating 210 is adjacent to the upper side of the upper top coating 202 adjoining one side surface of the middle substrate layer 201, and the upper hard coating 210 is composed of a successive covering of a first upper hard coating 204, a second upper hard coating 205, and a third upper hard coating 206. Furthermore, the lower hard coating 211 is adjacent to the lower side of the first lower top coating 203 adjoining the other side surface of the middle substrate layer 201, and the lower hard coating 211 is composed of a successive covering of a first lower hard coating 207, a second lower hard coating 208, and a third lower hard coating 209. In order for the hard coatings to achieve a surface pencil hardness of 6˜9H, the manufacturing process selectively uses a heat reactive resin, which can be a single or composite organic-inorganic material containing silicone, silica, and silicate, and the resin is coated adjacent to the top coatings, after which a stacking method is used to successively apply and cover the other hard coatings; the thickness of each of the hard coatings is ≤10 μm, and lies between 1˜10 μm. One or a combination of the light-transmitting materials: polyethylene terephthalate (PET), polycarbonate (PC), poly(methyl methacrylate) (PMMA), polyurethane (PU), thermoplastic polyurethane (TPU), polyamide (PA), triacetyl cellulose (TAC), PC/ABS (polycarbonate/acrylonitrile butadiene styrene), PC/PMMA, poly(ether sulphones) (PES), poly(ethylene 2,6-naphthalate (PEN), or polyimide (PI) is selectively used for the middle substrate layer 201, the thickness of which selectively lies between 7˜188 μm, which enables controlling the total thickness after the hard coating process to achieve a thickness of between 20˜250 μm, with a preferred total thickness of ≤120 μm. The light transmittance of the entire high hardness soft film structure is >85%, and radius of curvature is <10 cm; moreover, the soft film hardness can be adjusted to be 6-9H according to the coating thickness.

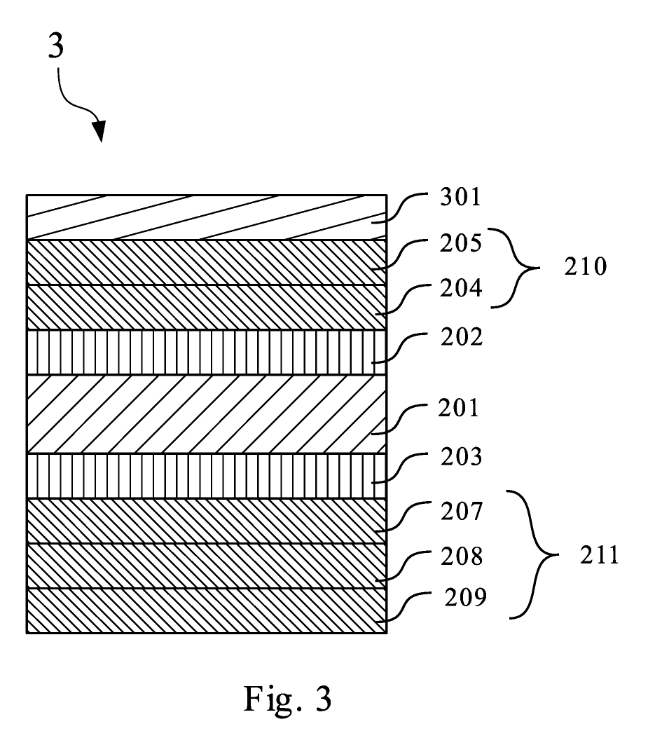

In another embodiment, referring to FIG. 3, which shows a cross sectional view of the high hardness soft film structure with an anti-pollution layer according to embodiments of the present invention, wherein an anti-pollution high hardness soft film structure 3 comprises the middle substrate layer 201 disposed between the upper top coating 202 and the first lower top coating 203, that is, the two side surfaces of the middle substrate layer 201 are respectively covered with the upper top coating 202 and the first lower top coating 203. The upper top coating 202 is disposed between the middle substrate layer 201 and the first upper hard coating 204; the first lower top coating 203 is disposed between the middle substrate layer 201 and the lower hard coating 211. The function of the top coatings lies in providing the interface between the middle substrate layer and the hard coatings with functional group affinity, to achieve a heterogeneous interfaces coupling effect. The upper top coating 202 has a thickness of ≤10 μm, and lies between 50 nm˜10 μm. The upper hard coating 210 is adjacent to the upper side of the upper top coating 202 adjoining one side surface of the middle substrate layer 201, and the upper hard coating 210 is composed of a successive covering of the first upper hard coating 204, the second upper hard coating 205, and an outermost upper anti-pollution layer 301. The anti-pollution layer 301 selective uses a composition of fluorine or non-fluorine heat reactive, high hardness coating material, and has a thickness that lies between 1˜10 μm. Furthermore, the lower hard coating 211 is adjacent to the lower side of the first lower top coating 203 adjoining the other side surface of the middle substrate layer 201, and the lower hard coating 211 is composed of a successive covering of the first lower hard coating 207, the second lower hard coating 208, and the third lower hard coating 209. In order for the hard coatings to achieve a surface pencil hardness of 6˜9H, the manufacturing process selectively uses a heat reactive resin, which can be a single or composite organic-inorganic material containing silicone, silica, and silicate, and the resin is coated adjacent to the top coatings, after which a stacking method is used to successively apply and cover the other hard coatings; the thickness of each of the hard coatings is ≤10 μm, and lies between 1˜10 μm. One of or a combination of the light-transmitting materials: polyethylene terephthalate (PET), polycarbonate (PC), poly(methyl methacrylate) (PMMA), polyurethane (PU), thermoplastic polyurethane (TPU), polyamide (PA), triacetyl cellulose (TAC), PC/ABS (polycarbonate/acrylonitrile butadiene styrene), PC/PMMA, poly(ether sulphones) (PES), poly(ethylene 2,6-naphthalate (PEN), or polyimide (PI) is selectively used for the middle substrate layer 201, the thickness of which selectively lies between 7˜188 μm, which enables controlling the total thickness after the hard coating process to achieve a thickness of between 20˜250 μm, with a preferred total thickness of ≤120 μm. The light transmittance of the entire high hardness soft film structure is >85%, and radius of curvature is <10 cm; moreover, the soft film hardness can be adjusted to be 6-9H according to the coating thickness.

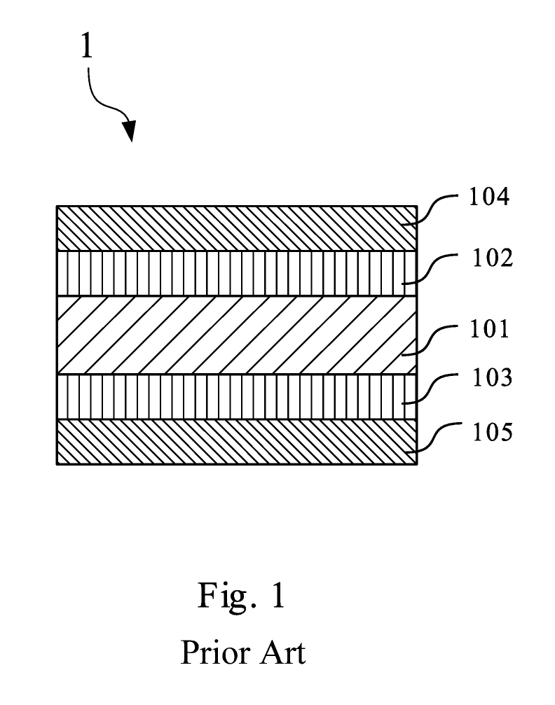

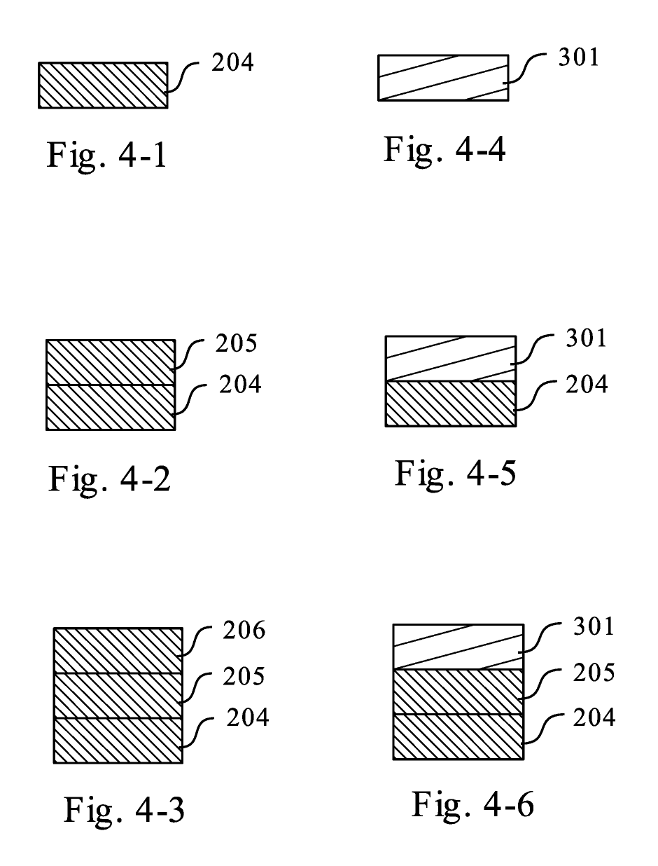

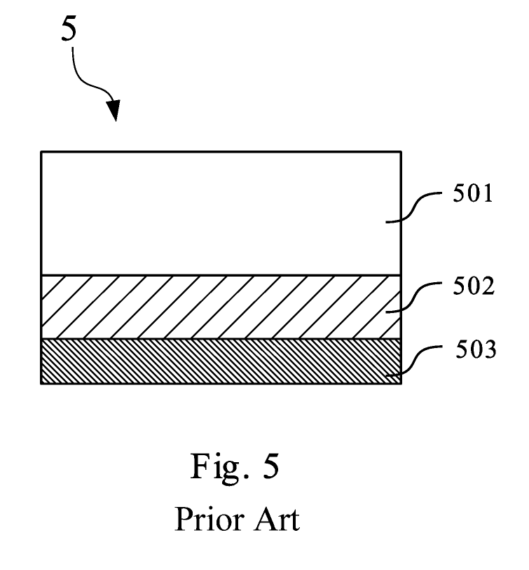

FIG. 4-1 shows a structural view of a single hard coating according to embodiments of the present invention, wherein the thickness of the first upper hard coating 204 lies between 1˜30 μm. Because the hardness and thickness assume a direct proportional relationship, as the thickness is increased the structure attains a pencil hardness of approximately 3H˜9H. Referring to FIG. 4-2, which shows a structural view of a two-layer hard coating according to embodiments of the present invention, wherein the first upper hard coating 204 and the second upper hard coating 205 are stacked to form the two-layer hard coating structure, and the thickness of each layer lies approximately between 1˜15 μm. Similarly, as the thickness is increased the structure attains a pencil hardness of approximately 6H˜9H. Furthermore, referring to FIG. 4-3, which shows a structural view of a tri-layer hard coating according to embodiments of the present invention, wherein the first upper hard coating 204, the second upper hard coating 205, and the third upper hard coating 206 are stacked to form a tri-layer hard coating structure, and the thickness of each layer lies approximately between 1˜10 μm. Similarly, as the thickness is increased the structure attains a pencil hardness of approximately 6H˜9H. The lower hard coatings are disposed in the same manner as the description of the above-mentioned embodiments of the upper hard coatings. In addition, an anti-pollution layer may also be used to serve as a surface structure to achieve high hardness and anti-pollution functions. Referring to FIG. 4-4, which shows a single anti-pollution layer according to embodiments of the present invention, wherein the thickness of the upper anti-pollution layer 301 lies between 1˜30 μm. The anti-pollution layer 301 selective uses a composition of fluorine or non-fluorine heat reactive, high hardness coating material, and has a thickness that lies between 1˜10 μm. Because the hardness and thickness assume a direct proportional relationship, as the thickness is increased the structure attains a pencil hardness of approximately 3H˜9H. Referring to FIG. 4-5, which shows a structural view of a single hard coating and a single anti-pollution layer according to embodiments of the present invention, wherein the first upper hard coating 204 and the upper anti-pollution layer 301 are stacked to form the single hard coating and single anti-pollution layer structure, and the thickness of each layer lies approximately between 1˜15 μm. Similarly, as the thickness is increased the structure attains a pencil hardness of approximately 6H˜9H. Furthermore, referring to FIG. 4-6, which shows a structural view of a two-layer hard coating and a single anti-pollution layer according to embodiments of the present invention, wherein the first upper hard coating 204, the second upper hard coating 205, and the upper anti-pollution layer 301 are stacked to form the two-layer hard coating and single anti-pollution layer structure, and the thickness of each layer lies approximately between 1˜10 μm. Similarly, as the thickness is increased the structure attains a pencil hardness of approximately 6H˜9H.

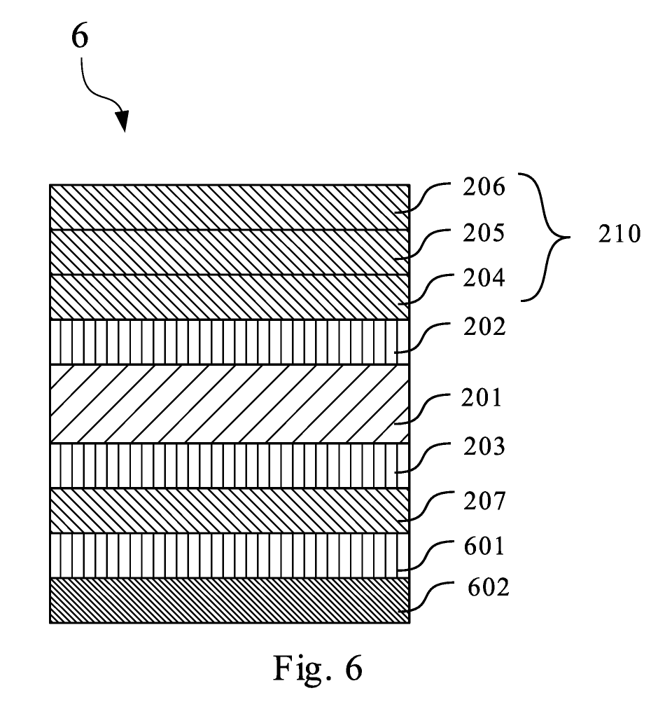

Referring to FIG. 6, which shows a cross sectional view of the high hardness soft film structure with a conductive layer of embodiments of the present invention, wherein a conductive high hardness soft film structure 6 is shown, and the two side surfaces of the middle substrate layer 201 are covered with the upper top coating 202 and the first lower top coating 203, respectively. The function of the top coatings lies in providing the interface between the middle substrate layer 201 and the hard coatings with functional group affinity, to achieve a heterogeneous interfaces coupling effect. Each of the top coatings has a thickness of ≤10 μm, and lies between 50 nm˜10 μm. The upper hard coating 210 is adjacent to the upper side of the upper top coating 202 adjoining one side surface of the middle substrate layer 201, and the upper hard coating 210 is composed of a successive covering of the first upper hard coating 204, the second upper hard coating 205, and the third upper hard coating 206. Furthermore, the first lower top coating 203 adjoining the other side surface of the middle substrate layer 201 is successively covered with the first lower hard coating 207, a second lower top coating 601, and an innermost conductive metal mesh layer 602. The function of the second lower top coating 601 lies in providing the interface between the hard coating and the conductive metal mesh layer 602 with functional group affinity, to achieve a heterogeneous interfaces coupling effect. The second lower top coating 601 has a thickness of ≤10 μm, and lies between 50 nm˜10 μm. The so-called metal mesh an be provided with a pattern structured directional conduction function, and has a thickness of ≤10 μm, and lies between 1˜10 μm. The surface of the conductive metal mesh layer 602 is covered with at least one protective layer. In order for the hard coating to achieve a surface pencil hardness of 6˜9H, the manufacturing process selectively uses heat reactive resin, which can be a single or composite organic-inorganic material containing silicone, silica, and silicate, and the resin is coated adjacent to the top coatings, after which a stacking method is used to successively apply and cover the other hard coatings; the thickness of each of the hard coatings is ≤10 μm, and lies between 1˜10 μm. One or a combination of the light-transmitting materials: polyethylene terephthalate (PET), polycarbonate (PC), poly(methyl methacrylate) (PMMA), polyurethane (PU), thermoplastic polyurethane (TPU), polyamide (PA), triacetyl cellulose (TAC), PC/ABS (polycarbonate/acrylonitrile butadiene styrene), PC/PMMA, poly(ether sulphones) (PES), poly(ethylene 2,6-naphthalate (PEN), or polyimide (PI) is selectively used for the middle substrate layer 201, the thickness of which selectively lies between 7˜188 μm, which enables controlling the total thickness after the hard coating process to achieve a thickness of between 20˜250 μm, with a preferred total thickness of ≤120 μm. The light transmittance of the entire high hardness soft film structure is >85%, and radius of curvature is <10 cm; moreover, the soft film hardness can be adjusted to be 6-9H according to the coating thickness.

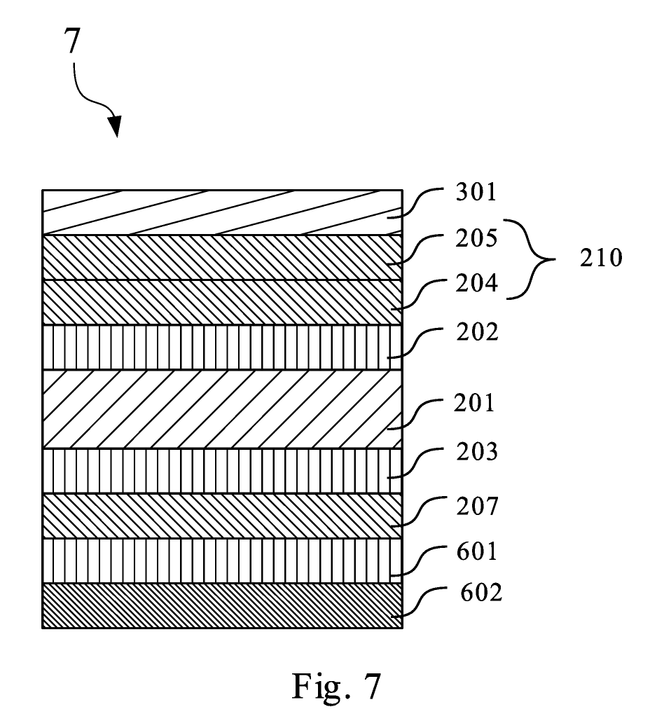

Another embodiment in the field of touch control applications is depicted in FIG. 7, which shows a cross sectional view of the high hardness soft film structure with an anti-pollution layer and a conductive layer according to embodiments of the present invention, wherein an anti-pollution and conductive high hardness soft film structure 7 is shown, and the two side surfaces of the middle substrate layer 201 are covered with the upper top coating 202 and the first lower top coating 203, respectively. The function of the top coatings lies in providing the interfaces between the middle substrate layer 201 and the hard coatings with functional group affinity, to achieve a heterogeneous interfaces coupling effect, the thickness of which ≤10 μm, and lies between 50 nm˜10 μm. The upper hard coating 210 is adjacent to the upper side of the upper top coating 202 adjoining one side surface of the middle substrate layer 201, and the upper hard coating 210 is composed of a successive covering of the first upper hard coating 204, the second upper hard coating 205, and the outermost upper anti-pollution layer 301. The anti-pollution layer 301 selectively uses a composition of fluorine or non-fluorine heat reactive, high hardness coating material of low surface energy, and has a thickness that lies between 1˜10 μm. Furthermore, the first lower top coating 203 adjoining the other side surface of the middle substrate layer 201 is successively covered with the first lower hard coating 207, the second lower top coating 601, and the innermost conductive metal mesh layer 602. The function of the second lower top coating 601 lies in providing the interface between the hard coating and the conductive metal mesh layer 602 with functional group affinity, to achieve a heterogeneous interfaces coupling effect. The second lower top coating 601 has a thickness of ≤10 μm, and lies between 50 nm˜10 μm. The so-called metal mesh an be provided with a pattern structured directional conduction function, and has a thickness of ≤10 μm, and lies between 1˜10 μm. The surface of the conductive metal mesh layer 602 is also covered with at least one protective layer. In order for the hard coatings to achieve a surface pencil hardness of 6˜9H, the manufacturing process selectively uses a heat reactive resin, which can be a single or composite organic-inorganic material containing silicone, silica, and silicate, and the resin is coated adjacent to the top coatings, after which a stacking method is used to successively apply and cover the other hard coatings; the thickness of each of the hard coatings is ≤10 μm, and lies between 1˜10 μm. One or a combination of the light-transmitting materials: polyethylene terephthalate (PET), polycarbonate (PC), poly(methyl methacrylate) (PMMA), polyurethane (PU), thermoplastic polyurethane (TPU), polyamide (PA), triacetyl cellulose (TAC), PC/ABS (polycarbonate/acrylonitrile butadiene styrene), PC/PMMA, poly(ether sulphones) (PES), poly(ethylene 2,6-naphthalate (PEN), or polyimide (PI) is selectively used for the middle substrate layer 201, the thickness of which selectively lies between 7˜188 μm, which enables controlling the total thickness after the hard coating process to achieve a thickness of between 20˜250 μm, with a preferred total thickness of ≤120 μm. The light transmittance of the entire high hardness soft film structure is >85%, and radius of curvature is <10 cm; moreover, the soft film hardness can be adjusted to be 6-9H according to the coating thickness.

Referring to FIGS. 2 to 4 and FIGS. 6 to 7, the present utility model provides a high hardness, anti-pollution, and conductive soft film structure, comprising at least one middle substrate layer 201, the upper top coating 202, a plurality of the upper hard coatings 210, at least one upper anti-pollution layer 301, the first lower top coating 203, a plurality of the lower hard coatings 211, the second lower top coating 601, and at least one conductive metal mesh layer 602, whereby embodiments of the present invention is correspondingly structured with characteristics including: top coatings and a plurality of hard coatings of high hardness material are successively applied to the upper and lower sides of the middle substrate layer with high light transmittance to increase scratch and wear resistivity of the entire structure from external forces; one side of the outermost upper hard coating 210 is covered with the low surface energy, upper anti-pollution layer 301; and the second lower top coating 601 and the conductive metal mesh layer 602 material successively applied to the first lower hard coating 207. Accordingly, embodiments of the present invention achieves high hardness, anti-pollution, and conductive soft film structure for optical use. The present utility model is able to directly replace conductive glass substrates, and is further provided with greater thinness characteristics, and thus distinct and differentiable from prior art. Embodiments of the present invention are indeed provided with originality, advancement, and practical effectiveness, and enables effective improvements on the shortcomings of the prior art; moreover, embodiments of the present invention have considerable practicability in use.

In conclusion, the concrete structures of the embodiments disclosed in the present invention can certainly provide packaging for food products and medicine products, and has flexible thin film applications for electronic component use in solar cells, electronic paper, organic electroluminescent (EL) displays, and the like. Furthermore, the overall structure of embodiments of the present invention has not been seen in like products, and the contents of this specification have not been publicly disclosed prior to this application. The practicability and advancement of embodiments of the present invention clearly comply with the essential elements as required for a new patent application, accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A high hardness soft film structure, comprising:
a middle substrate layer, which is disposed between an upper top coating and a first lower top coating;
the upper top coating, which is disposed between the middle substrate layer and an upper hard coating;
at least one upper hard coating, which is adjacent to one side of the upper top coating;
the first lower top coating, which is disposed between the middle substrate layer and a lower hard coating; and
at least one lower hard coating, which is adjacent to one side of the first lower top coating; whereby the structure is correspondingly constructed;
wherein the top coatings and hard coatings of high hardness material are respectively applied to the upper and lower sides of the middle substrate layer with high light transmittance, thereby increasing scratch and wear resistivity of the entire structure from external forces.

2. A high hardness soft film structure, comprising:
a middle substrate layer, which is disposed between an upper top coating and a first lower top coating;
the upper top coating, which is disposed between the middle substrate layer and an upper hard coating;
at least one upper hard coating, which is adjacent to one side of the upper top coating;
a first lower top coating, which is disposed between the middle substrate layer and a lower hard coating;
at least one lower hard coating, which is adjacent to one side of the first lower top coating;
a second lower top coating, which is disposed between the lower hard coating and a conductive metal mesh layer; and
at least one conductive metal mesh layer, which is adjacent to one side of the second lower top coating; whereby the structure is correspondingly constructed;
wherein the top coatings and a plurality of the hard coatings of high hardness material are respectively applied to the upper and lower sides of the middle substrate layer with high light transmittance, thereby increasing scratch and wear resistivity of the entire structure from external forces; as well as comprising coatings of the second lower top coating and the conductive metal mesh layer conductive material.

3. The high hardness soft film structure according to claim 2, wherein the conductive metal mesh layers are provided with a pattern structured directional conduction function; the conductive metal mesh layers have a thickness of ≤10 μm, and lies between 1˜10 μm, and the surface of the conductive metal mesh layers are covered with at least one protective layer.

4. The high hardness soft film structure according to claim 1, wherein at least one upper anti-pollution layer is disposed adjacent to one side surface of an outermost upper hard coating, or at least one upper anti-pollution layer replaces the upper hard coating and covers one side of the upper top coating.

5. The high hardness soft film structure according to claim 4, wherein the upper anti-pollution layers are selectively composed of a fluorine or non-fluorine heat reactive, high hardness coating of low surface energy, which have a thickness that lies between 1˜30 μm.

6. The high hardness soft film structure according to claim 2, wherein at least one upper anti-pollution layer is disposed adjacent to one side surface of the outermost upper hard coating, or at least one upper anti-pollution layer replaces the upper hard coating and covers one side of the upper top coating.

7. The high hardness soft film structure according to claim 6, wherein the upper anti-pollution layers are selectively composed of a fluorine or non-fluorine heat reactive, high hardness coating of low surface energy, which have a thickness that lies between 1˜30 μm.

8. The high hardness soft film structure according to claim 1, wherein the middle substrate layer selectively uses one or a combination of the light-transmitting materials: polyethylene terephthalate (PET), polycarbonate (PC), poly(methyl methacrylate) (PMMA), polyurethane (PU), thermoplastic polyurethane (TPU), polyamide (PA), triacetyl cellulose (TAC), PC/ABS (polycarbonate/acrylonitrile butadiene styrene), PC/PMMA, poly(ether sulphones) (PES), poly(ethylene 2,6-naphthalate (PEN), or polyimide (PI); the thickness of the middle substrate layer lies between 7˜188 μm.

9. The high hardness soft film structure according to claim 2, wherein the middle substrate layer selectively uses one or a combination of the light-transmitting materials: polyethylene terephthalate (PET), polycarbonate (PC), poly(methyl methacrylate) (PMMA), polyurethane (PU), thermoplastic polyurethane (TPU), polyamide (PA), triacetyl cellulose (TAC), PC/ABS (polycarbonate/acrylonitrile butadiene styrene), PC/PMMA, poly(ether sulphones) (PES), poly(ethylene 2,6-naphthalate (PEN), or polyimide (PI); the thickness of the middle substrate layer lies between 7˜188 μm.

10. The high hardness soft film structure according to claim 1, wherein each of the top coatings provide the interfaces between adjacent layers with functional group affinity, and each of the top coatings has a thickness that lies between 50 nm˜10 μm.

11. The high hardness soft film structure according to claim 2, wherein each of the top coatings provide the interfaces between adjacent layers with functional group affinity, and each of the top coatings has a thickness that lies between 50 nm˜10 μm.

12. The high hardness soft film structure according to claim 1, wherein the material for each of the hard coatings selectively uses heat reactive resin, and each of the hard coatings has a thickness that lies between 1˜30 μm.

13. The high hardness soft film structure according to claim 12, wherein the heat reactive resin is a single or composite organic-inorganic material that contains silicone, silica, and silicate.

14. The high hardness soft film structure according to claim 2, wherein the material for each of the hard coatings selectively uses heat reactive resin, and each of the hard coatings has a thickness that lies between 1˜30 μm.

15. The high hardness soft film structure according to claim 14, wherein the heat reactive resin is a single or composite organic-inorganic material that contains silicone, silica, and silicate.

16. The high hardness soft film structure according to claim 1, wherein the entire thickness lies between 20˜250 μm, with a preferred entire thickness of ≤120 μm.

17. The high hardness soft film structure according to claim 2, wherein the entire thickness lies between 20˜250 μm, with a preferred entire thickness of ≤120 μm.

18. The high hardness soft film structure according to claim 1, wherein the entire light transmittance is >85%, and radius of curvature is <10 cm.

19. The high hardness soft film structure according to claim 2, wherein the entire light transmittance is >85%, and radius of curvature is <10 cm.

20. The high hardness soft film structure according to claim 1, wherein the soft film hardness is adjustable to 3-9H according to the coating thickness.

21. The high hardness soft film structure according to claim 2, wherein the soft film hardness is adjustable to 3-9H according to the coating thickness.
